(19) United States
(12) Patent Application Publication
(10) Pub. No.: US 2007/0144045 A1
(43) Pub. Date: Jun. 28, 2007

(54) Electroluminescent display system

(75) Inventors: Frank Edward Anderson, Sadieville, KY (US); Bryan Dale McKinley, Lexington, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(73) Assignee: Lexmark International, Inc.

(21) Appl. No.: 11/316,769

(22) Filed: Dec. 23, 2005

(51) Int. Cl. G09F 13/22

(52) U.S. Cl. 40/544

(57) ABSTRACT

Electroluminescent (EL) display systems and methods for illuminating an EL display system. One such EL display system includes an electroluminescent (EL) signage having an associated image, a printed conductor pattern, and a plurality of electrical contacts pads associated with the conductor pattern. A frame having a plurality of electrical contacts for operable connection with the contacts of the EL signage is provide. The frame is adapted to at least partially receive the EL signage and cause the EL signage to be in electrical communication with a power source and a microcontroller for activating the EL signage in a predetermined pattern.

### FIELD OF THE DISCLOSURE

The disclosure is directed to an electroluminescent (EL) display systems and, in particular, to systems for assembling and using EL signage.

### BACKGROUND AND SUMMARY

Signage, such as a sign, display, billboard, symbol or a poster, can be used to attract the attention of consumers. Signage can be illuminated or non-illuminated. Illumination of signage is often provided by incandescent or fluorescent lighting systems which are expensive to construct and operate.

In order to provide lower cost illumination of signs, displays, billboards, and the like, newer, lower cost illumination devices may be used. For example, one type of signage in use today uses electroluminescence (EL) technology to create a display in which parts of the image emit light. Illumination of the signage is provided by placing alternating electric fields across a layer of electroluminescent material that is sandwiched between a transparent conductor layer and a second conductor layer usually with an intervening dielectric to prevent voltage breakdown.

A translucent substrate having an image printable layer may be applied to an electroluminescent substrate containing the electroluminescent material and an image may be printed on the image printable layer. Upon activation of the electroluminescent material, the image is illuminated. Construction of one such electroluminescent signage is described for example in U.S. Publication No. 2002/0090495, the disclosure of which is incorporated herein by reference.

Conventional EL display systems are typically highly customized. Hence, everything from the signage to the driving electronics is unique to a particular end use of the signage. Thus, the user's ability to implement changes to the signage is limited and changes or alterations of the signage may be extremely costly.

Another disadvantage of conventional electroluminescent display systems is that illumination of the entire electroluminescent signage at one time is usually required. Accordingly, it is difficult to provide selective illumination or the appearance of motion. Accordingly, there remains a need for improved electroluminescent display systems.

With regard to the foregoing needs, exemplary embodiments of the disclosure provide, for example, electroluminescent (EL) display systems and methods for illuminating an EL display system. One such EL display system includes an electroluminescent (EL) signage having an associated image, a printed conductor pattern, and a plurality of electrical contacts associated with the conductor pattern. A frame having a plurality of electrical contacts for operable connection with the contacts of the EL signage is provide. The frame is adapted to at least partially receive the EL signage and cause the EL signage to be in electrical communication with a power source and a microcontroller for activating the EL signage in a predetermined pattern.

Another exemplary embodiment of the disclosure provides a method for illuminating an image printed adjacent an electroluminescent (EL) substrate. The substrate has a conductive pattern and a plurality of electrical contacts associated therewith. The EL substrate is physically associated with a frame having a plurality of electrical contacts for operable connection with the contacts of the EL substrate. A microcontroller and power source are provided for activating the conductive pattern of the EL substrate. The conductive pattern is activated to cause illumination of the EL substrate in a predetermined pattern.

An advantage of at least some of the foregoing embodiments is that customized signage using EL materials may be made at or proximate to a customer's site using relatively inexpensive imaging apparatus, such as printers. The resulting EL signage may be, for example, interchangeably inserted into a frame for selectively illuminating portions of the EL material in the signage. Hence, signage may be provided that enables a wider range of design features and improved interchangeability. The systems described herein might also enable power to be applied to selective conductors with respect to time to give the appearance of motion.

### BRIEF DESCRIPTION OF THE DRAWINGS

Further advantages of the exemplary embodiments may become apparent by reference to the detailed description when considered in conjunction with the elements through the several views, and wherein:

FIG. 1 is a cross-sectional view, not to scale, of an electroluminescent (EL) signage for an EL system according to the disclosure;

FIG. 2 is plan view, not to scale, of an EL signage system according to the disclosure;

FIG. 3 is a perspective view, not to scale, of an EL signage frame according to an alternate embodiment of the disclosure; and

FIG. 4 is a schematic diagram of a control system for an EL signage system according to the disclosure.

### DETAILED DESCRIPTION OF EXEMPLARY EMBODIMENTS

As described in more detail below, one embodiment of the disclosure provides a system and method for providing improved EL signage and display systems. A pattern(s) may be printed on an EL substrate to provide, for example, a customized sign or display that is receivable into a separate frame (which might also be referred to, in some embodiments, as a sign or display holder). The pattern(s) may correspond to encoded information that enables a controller in the display holder to selectively illuminate portions of the sign. Since the system enables interchangeability of signs with the holder, a number of different signs may be used with a single sign holder enabling a user to quickly change the sign and its display options.

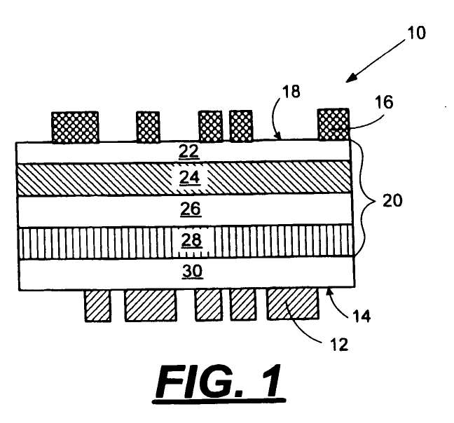

With reference to FIG. 1, there is provided a cross-sectional view of an EL signage 10 including an image pattern 12 printed adjacent (e.g., on) a first surface 14 thereof and a conductor pattern 16 printed adjacent (e.g., on) a second surface 18 thereof. The substrate 20 is an EL substrate. Current commercially available EL substrates 20 typically include an insulative or dielectric layer 22, an EL material layer 24, a translucent conductor layer 26, and a translucent protective layer 28. An image receiving layer 30 may be applied to the translucent protective layer 28 to provide a suitable surface for receiving the image pattern 12.

In an exemplary embodiment, the image pattern 12 may be provided by an imaging substance, such as monochrome or color inks. Such a substance may be applied to the image receiving layer 30 using, for example, screen printing, rotogravure printing, flexographic printing, lithographic printing, laser printing, ink jet printing, and the like. More flexibility in applying an image to the image receiving layer 30 may be provided by ink jet printing as described in U.S. Publication No. 2002/0090495.

The conductor pattern 16 applied to the dielectric layer 22 may likewise be applied by a wide variety of printing techniques including, but not limited to, vacuum deposition, chemical vapor deposition, electroplating, screen printing, rotogravure printing, flexographic printing, lithographic printing, and ink jet printing. The conductive pattern 16 may be a single conductive layer or, as shown in FIG. 1, may be a particular conductor pattern on the dielectric layer 22. Conductive inks that may be used to provide the conductor pattern 16 by a printing method, include, but are not limited to inks containing copper, silver, or carbon particles. In order to provide increased flexibility for design and operation of the EL signage, a conductive ink may be applied by a micro-fluid ejection device. The thickness of the conductor pattern 16 may range from about 0.5 to about 5.0 microns. As described in more detail below, electrical contacts (e.g., contact pads) are provided in electrical communication with the conductor pattern 16 for connection to a frame, such as a sign holder.

The insulative or dielectric layer 22 typically has a thickness ranging from about 20 to about 200 microns and may be provided by a material having a dielectric constant at 20° C. of greater than about fifty. Suitable materials having relatively high dielectric constants include, but are not limited to, barium or strontium titanate dispersed in a polymeric material, and titanium dioxide dispersed in a polymeric material. A particularly suitable polymeric material for dispersing the barium, strontium, or titanium compounds is a fluoropolymer material such as poly(tetrafluoroethylene). Accordingly, a particularly suitable dielectric layer 22 includes barium titanate dispersed in a fluoropolymer layer.

The EL layer 24 may include organic and/or inorganic EL materials. Inorganic materials typically provide brighter luminous characteristics and may be selected from terbium-doped zinc sulfide (ZnS:Tb), manganese-doped zinc sulfide (ZnS:Mn), cerium-doped yttrium aluminum garnet (YAG:Ce), copper-doped zinc selenium sulfide (ZnSeS:Cu), europium-doped strontium barium silicon oxide (SrBaSiO4:Eu), cerium-doped strontium sulfide (SrS:Ce), copper-doped strontium sulfide (SrS:Cu), copper and silver-doped strontium sulfide (SrS:Cu,Ag), and the like. The thickness of the EL layer 24 may range from about 100 nanometers to about 5 microns.

The conductor layer 26 of the EL substrate 20 is typically made of a translucent conductive material such as indium tin oxide (ITO) and has a thickness ranging from about 50 to about 10,000 Angstroms. A protective transparent or translucent protective layer 28 is applied to the translucent conductor layer 26. The layer 28 may be selected from polyethylene terephthalate, polybutylene terephthalate, polycarbonate, and the like. The thickness of the protective layer 28 may range from about 20 to about 150 microns. The EL substrate 20 is relatively thin and ideally flexible so that it can be easily handled in an imaging apparatus, such as an ink jet printer. Overall, the thickness of the EL substrate 20 ranges from about 0.1 to about 0.5 millimeters. EL substrates 20 as described above are commercially available from BKL, Inc. of King of Prussia, Pa., Luminescent Systems, Inc. of Lebanon, N.H., and Edmund Optics, Inc. of Barrington, N.J.

An image receiving layer 30, such as an ink receptive layer, can be applied adjacent (e.g., to) the protective layer 28 of the EL substrate 20. An ink receptive layer, for example, may be provided by a wide variety of micro-porous organic or inorganic materials that are compatible with the ink applied to form the image pattern 12. One such ink receptive layer is a layer of fumed silica in a binder. The thickness of the ink receptive layer may range from about 20 to about 150 microns.

The ink receptive layer may be applied to the protective layer 28 by a wide variety of coating techniques, include but not limited to, roll coating, doctor blade coating, spray coating, dipping, screen coating, and the like. However, in order to minimize the cost of the EL signage 10, the ink receptive layer may be applied by a micro-fluid ejection device in the same pattern as the image pattern 12, since the image pattern is not applied to the entire area of the EL substrate 20.

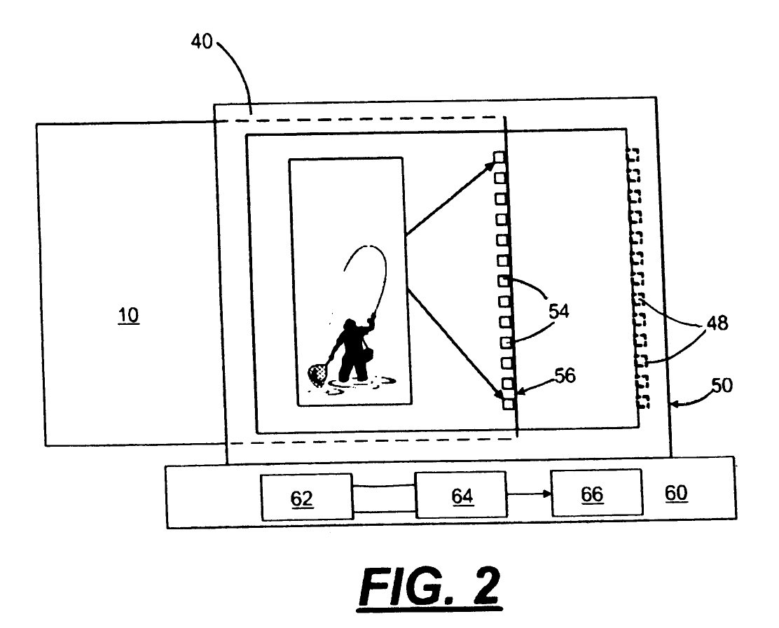

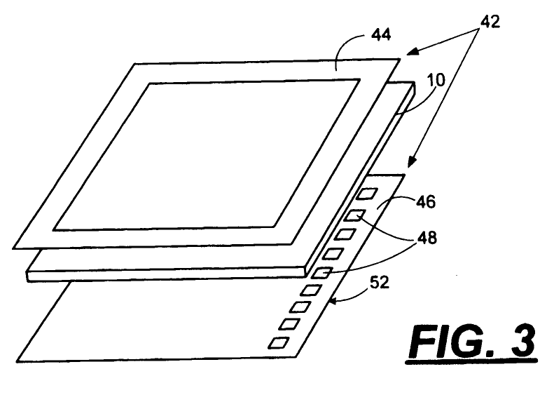

As illustrated in FIG. 2, another element of the EL display system is a frame 40, such as one for removably receiving the EL signage 10 described above. The frame 40 may be adapted for slidably receiving the EL signage 10 therein as shown in FIG. 2. In one alternative, as shown in FIG. 3, a frame 42 may containing an upper frame section 44 and lower frame section 46 that may be removably attached to one another with the EL signage 10 placed between the upper and lower frame sections 44 and 46. In another alternative, the upper and lower frame sections may be hingedly attached to one another.

The frame 40 or 42 may have electrical contacts 48 disposed on one end 50 or 52 thereof for electrical contact communication with contact pads 54 on the EL signage 10. The electrical contacts 48 are desirably spring loaded contacts that make a positive electrical connection with the contact pads 54.

As shown in FIGS. 2 and 3, the contact pads 54 are disposed on a leading edge 56 of the EL signage 10. However, it will be appreciated that the contact pads 54 may be disposed along two or more edges of the EL signage 10 or, such as in the case of frame 42, may be located at any intermediate location on the EL signage 10 between the edges. However, locating the contact pads 54 along the leading edge 56 of the EL signage 10 enables increased flexibility with regard to construction of alternate EL signs 10 for use with frames 40 or 42. As with the conductor layer 16, the contact pads 54 may be printed onto the EL signage 10 in a location for electrical communication with the electrical contacts 48 on the frame 40 or 42.

The frame 40 or 42, may be removably attached to a base 60 (FIG. 2) having a power source 62, a microcontroller 64, and EL driver circuits 66. Selective illumination of the EL signage 10 may be obtained by the detection or absence of certain of the contact pads 54 on the EL signage 10. Low cost microcontrollers 64 may be used to detect the contact pads 54 providing an EL signage pattern and to provide the needed sequencing and timings required to implement the desired display features. For example, the microcontroller 64 can interface with the EL driver circuits 66 to activate selective portions of the EL layer 24 to cause illumination thereof. Conventional integrated circuits (IC's) may be used to provide the EL driver circuits 66. In the alternative, the microcontroller 64 and the EL driver circuits 66 may be combined into a single customized integrated circuit to provide a further cost improvement for the EL signage 10.

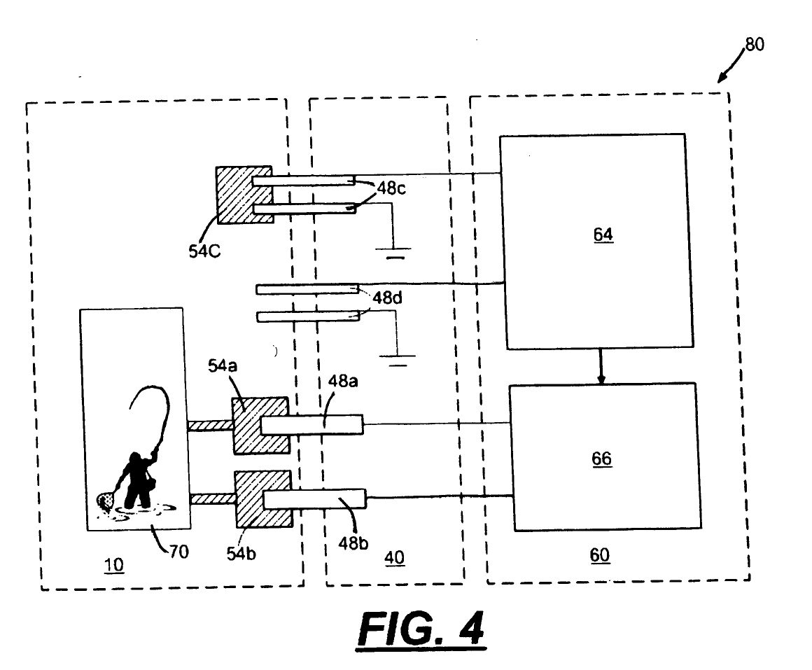

A schematic illustration of an encoded pattern used to provide input to the microcontroller 64 is illustrated in FIG. 4. According to FIG. 4, the EL signage 10 has a single image 70 thereon that is illuminated by activation of contact pads 54a and 54b by EL driver circuits 66 through electrical contacts 48a and 48b. Selective activation of contact pads 54a and 54b is provided by encoded information obtained by electrical contacts 48c and 48d. In the case of contacts 48c, contact pad 54c provides a logic low signal to the microcontroller 64 because there is current flowing through the electrical contacts 48c to ground. Conversely, contacts 48d provide a logic high signal to the microcontroller 64 because of the absence of a contact pad as shown.

The foregoing illustration provides an EL display system 80 with a single image. However, the concept may be expanded to provide an EL display system with multiple images. For example, there may be provided an EL signage 10 having up to 3 separate images associated with three separate EL substrates. Each of the images may be displayed in any order and each may either blink on or be on continuously. Also, for each image, the delay time between steps in an illumination sequence may be either “normal” or “long”.

In the foregoing example, there are ten contact pad locations wherein the contact pad 48 may be present or absent as shown in FIG. 4. Four of the ten contact pad locations may be used to encode fifteen sequencing possibilities as follows:

1) Image 1 only

2) Image 2 only

3) Image 3 only

4) Image 1 then Image 2

5) Image 2 then Image 1

6) Image 1 then Image 3

7) Image 3 then Image 1

8) Image 2 then Image 3

9) Image 3 then Image 2

10) Image 1 then Image 2 then Image 3

11) Image 1 then Image 3 then Image 2

12) Image 2 then Image 1 then Image 3

13) Image 2 then Image 3 then Image 1

14) Image 3 then Image 1 then Image 2

15) Image 3 then Image 2 then Image 1

For each image, two contact pad locations may be used to set (1) blink/on steady and (2) normal/long step delay. Hence, two contact pad locations are used for each of the three images providing a total of ten contact pad locations for the three images and the sequences described above.

It will be appreciated that since the contact pads 48 are disposed on the EL signage 10, different signage may be provided with different images and encoded sequences while still using the same frame 40 and base 60. Hence the system 80 may provide a user with enhanced flexibility with respect to EL signage.

It is contemplated, and will be apparent to those skilled in the art from the preceding description and the accompanying drawings, that modifications and changes may be made in the embodiments of the disclosure. Accordingly, it is expressly intended that the foregoing description and the accompanying drawings are illustrative of preferred embodiments only, not limiting thereto, and that the true spirit and scope of the present disclosure be determined by reference to the appended claims.

What is claimed is:

1. An electroluminescent (EL) display system comprising:
an electroluminescent (EL) signage having an associated image, a printed conductor pattern, and a plurality of electrical contacts associated with the conductor pattern; and
a frame having a plurality of electrical contacts for operable connection with the contacts of the EL signage, wherein the frame is adapted to at least partially receive the EL signage and cause the EL signage to be in electrical communication with a power source and a microcontroller for activating the EL signage in a predetermined pattern.

2. The EL display system of claim 1, wherein the electrical contacts of the signage are disposed on a leading edge of the EL signage.

3. The EL display system of claim 2, wherein the electrical contacts of the frame are disposed adjacent a first edge of the frame.

4. The EL display system of claim 1, wherein the electrical contacts of the signage are provided in a pattern that provides encoded information to the microcontroller.

5. The EL display system of claim 1, further comprising a base attached to the frame, wherein the base contains the power source and microcontroller.

6. The EL display system of claim 5, wherein the base further comprises driver circuits for the EL display system wherein the driver circuits are controlled by the microcontroller.

7. The EL display system of claim 1, wherein the conductor pattern comprises a pattern formed by conductive ink printed by a micro-fluid ejection device.

8. The EL display system of claim 1, wherein the frame is adapted for sliding connection between the contacts of the signage and the contacts of the frame.

9. A method for illuminating an image printed adjacent an electroluminescent (EL) substrate having a conductive pattern and a plurality of electrical contacts associated therewith, the method comprising:
physically associating the EL substrate with a frame having a plurality of electrical contacts for operable connection with the contacts of the EL substrate, and having a microcontroller and power source associated therewith for activating the conductive pattern of the EL substrate; and
activating the conductive pattern to cause illumination of the EL substrate in a predetermined pattern.

10. The method of claim 9, wherein the electrical contacts of the substrate are disposed on a leading edge of the EL substrate and the electrical contacts of the frame are disposed adjacent a first edge of the frame.

11. The method of claim 10, wherein the EL substrate is physically associating with the frame by sliding the EL substrate into the frame.

12. The method of claim 9, wherein the electrical contacts of the substrate are provided in a pattern that provides encoded information to the microcontroller, further comprising inputting the encoded information into the microcontroller.

13. The method of claim 9, further comprising a base associated with the frame, wherein the base further comprises driver circuits for the EL substrate, further comprising outputting a signal to the driver circuits from the microcontroller to illuminate the EL substrate in the predetermined pattern.

14. The method of claim 9, further comprising printing the conductive pattern by ejecting a conductive ink from a micro-fluid ejection device.

15. The method of claim 9, wherein the microcontroller provides selective activation of the EL substrate sufficient to provide an image having an appearance of motion.

16. Electroluminescent (EL) signage for use in an electroluminescent (EL) display system comprising a frame having a plurality of electrical contacts, and a power source and a microcontroller, the signage comprising an EL substrate capable of receiving an image and a printed conductor pattern, and having a plurality of electrical contacts associated with the conductor pattern for operable connection with the contacts of the frame, wherein the EL signage is adapted to be at least partially received in the frame to cause the EL signage to be in electrical communication with the frame for activating the EL signage in a predetermined pattern.

17. A frame for use in an electroluminescent (EL) display system comprising an electroluminescent (EL) signage having an associated image, a printed conductor pattern, and a plurality of electrical contacts associated with the conductor pattern, the frame comprising a plurality of electrical contacts for operable connection with the contacts of the EL signage, wherein the frame is adapted to at least partially receive the EL signage and cause the EL signage to be in electrical communication with a power source and a microcontroller for activating the EL signage in a predetermined pattern.
